(19) United States
(12) Patent Application Publication
(10) Pub. No.: US 2026/0349484 A1
(43) Pub. Date: Nov. 5, 2026

(54) AMBIENT TEMPERATURE ESTIMATION AND DEVICE OPTIMIZATION

(71) Applicant: Microsoft Technology Licensing, LLC, Redmond, WA (US)

(72) Inventors: Gregory Allen NIELSEN, Kirkland, WA (US); Mark Anthony ANDERSON, JR., West Henrietta, NY (US); Xiaoting QIN, Beijing (CN); Jue ZHANG, Beijing (CN); Cho Yu CHONG, Kirkland, WA (US)

(21) Appl. No.: 19/120,760

(22) PCT Filed: Nov. 10, 2022
(86) PCT No.: PCT/CN2022/131031

§ 371 Date: Apr. 11, 2025

(51) Int. Cl. G06F 1/20; G01K 3/10; G01K 3/14; G01K 7/42; G06F 1/28; H05K 7/20

(52) U.S. Cl. CPC G06F 1/206; G01K 3/10; G01K 3/14; G01K 7/427; G06F 1/28; H05K 7/20209

(57) ABSTRACT

Methods, systems and computer program products are provided for ambient temperature estimation and device optimization. A computing device may estimate (e.g., predict based on a thermal model) an ambient temperature outside the device as a difference between a first sum and a second sum. The first sum may comprise, for example, one or more of a first temperature in the computing device (e.g., a temperature of a power supply, such as a battery), a rate of change of a second temperature in the computing device, and/or heat dissipation by the computing device (e.g., passive dissipation, such as conduction, and/or active dissipation, such as a fan). The second sum may comprise, for example, one or more of a computing device workload (e.g., system, CPU and/or GPU power consumption) and/or a difference between a third temperature in the computing device (e.g., internal air temperature near a power supply) and the ambient temperature.

### BACKGROUND

Computing device performance may be limited (e.g., throttled) based on ergonomic and/or safety reasons (e.g., IEC safety standards 60950 and 62368). For example, handheld or laptop computing device performance may be reduced to maintain an ergonomic noise level and/or temperature in areas that may come in contact with a human for extended periods of time (e.g., long touch areas).

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Methods, systems and computer program products are provided for ambient temperature estimation and device optimization (e.g., using an ordinary differential equation). Device performance may be boosted in thermally restrictive scenarios (e.g., high ambient temperature environments), for example, by tracking ambient temperature. Ambient temperature may be (e.g., accurately) estimated and used, for example, to enable a device to recognize high ambient temperature environments and adjust one or more operational parameters (e.g., limits/thresholds), such as a target thermal (e.g., touch temperature) limit, an acoustic (e.g., fan) profile limit, a power limit, etc. For example, raising a target touch temperature and/or a fan profile limit in a high temperature environment based on ambient temperature estimates may (e.g., significantly) improve device performance (e.g., by avoiding performance throttling that may otherwise occur if ambient temperature is unknown or inaccurately estimated).

A (e.g., mobile) computing device may include a temperature estimator configured to estimate (e.g., predict based on a thermal model) an ambient temperature outside the computing device as a difference between a first sum and a second sum. The first sum may comprise, for example, (e.g., a sum of) one or more of a first temperature in the computing device (e.g., a temperature of a power supply, such as a battery), a rate of change of a second temperature in the computing device, and/or heat dissipation by the computing device (e.g., passive dissipation, such as conduction, and/or active dissipation, such as a fan). The second sum may comprise, for example, (e.g., a sum of) one or more of a computing device workload (e.g., system, CPU and/or GPU power consumption), and/or a difference between a third temperature in the computing device (e.g., internal air temperature near a power supply) and the ambient temperature.

Further features and advantages of the invention, as well as the structure and operation of various embodiments, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form a part of the specification, illustrate embodiments of the present application and, together with the description, further serve to explain the principles of the embodiments and to enable a person skilled in the pertinent art to make and use the embodiments.

FIG. 1 shows a block diagram of an example computing environment for ambient temperature estimation and device optimization, according to an embodiment.

FIG. 2 shows a block diagram of an example of developing a model for ambient temperature estimation and device optimization, according to an embodiment.

FIG. 3 shows a block diagram of an example of using a model for ambient temperature estimation, according to an embodiment.

FIG. 4 shows a block diagram of an example of using estimated ambient temperature estimation for device optimization, according to an embodiment.

FIG. 5 shows a flowchart of an example method for ambient temperature estimation and device optimization, according to an embodiment.

FIG. 6 shows a block diagram of an example computing device that may be used to implement example embodiments.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### I. Introduction

The present specification and accompanying drawings disclose one or more embodiments that incorporate the features of the present invention. The scope of the present invention is not limited to the disclosed embodiments. The disclosed embodiments merely exemplify the present invention, and modified versions of the disclosed embodiments are also encompassed by the present invention. Embodiments of the present invention are defined by the claims appended hereto.

Numerous exemplary embodiments are described as follows. It is noted that any section/subsection headings provided herein are not intended to be limiting. Embodiments are described throughout this document, and any type of embodiment may be included under any section/subsection. Furthermore, embodiments disclosed in any section/subsection may be combined with any other embodiments described in the same section/subsection and/or a different section/subsection in any manner.

### II. Example Implementations

As noted in the Background Section, above, computing device performance may be limited (e.g., throttled) based on ergonomic and/or safety reasons (e.g., IEC safety standards 60950 and 62368). For example, handheld or laptop computing device performance may be reduced to maintain an ergonomic noise level and/or temperature in areas that may come in contact with a human for extended periods of time (e.g., long touch areas). A user using a device in a high ambient temperature area may experience unnecessary throttling due to overall increases in device temperatures.

Methods, systems and computer program products are provided for ambient temperature estimation and device optimization (e.g., using an ordinary differential equation). A (e.g., mobile) computing device may include a temperature estimator configured to estimate (e.g., predict based on a thermal model) an ambient temperature outside the computing device as a difference between a first sum and a second sum. The first sum may comprise, for example, (e.g., a sum of) one or more of a first temperature in the computing device (e.g., a temperature of a power supply, such as a battery), a rate of change of a second temperature in the computing device, and/or heat dissipation by the computing device (e.g., passive dissipation, such as conduction, and/or active dissipation, such as a fan). The second sum may comprise, for example, (e.g., a sum of) one or more of a computing device workload (e.g., system, CPU and/or GPU power consumption) and/or a difference between a third temperature in the computing device (e.g., internal air temperature near a power supply, such as in a space between the power supply and a chassis of the computing device) and the ambient temperature.

Ambient temperature estimation may be implemented by using (e.g., raw or processed) measurements by a device to predict the temperature outside of the device (e.g., an in situ ambient temperature). Accurate estimation of ambient temperature may support performance tuning (e.g., optimization) for computing devices, which may be subject to performance throttling to satisfy ergonomic and/or safety rules of operation. In some examples, ambient temperature estimated by one or more devices may be provided as telemetry data, which may be used to control operation of one or more devices, systems, etc. For example, a heating ventilation and air conditioning (HVAC) system in a building may receive telemetry data (e.g., estimated ambient temperature) throughout the building from one or more (e.g., fixed or mobile) devices, and may use the telemetry data to dynamically adjust HVAC operation (e.g., heating, cooling, ventilation) in general and/or specific areas accordingly.

Computing devices may have thermal and acoustic limitations regardless of the environment that the users of the computing devices are in, for example, to comply with ergonomic and/or safety standards for “long touch” areas and/or manufacturer comfort guidelines. In various locations with high ambient temperature conditions, computing device measurements (e.g., temperature, noise) may exceed ergonomic and/or safety limits, which may lead to thermal and/or acoustic throttling and an overall reduction of device performance.

Device performance may be boosted in thermally restrictive scenarios (e.g., high ambient temperature environments), for example, by tracking ambient temperature. Ambient temperature may be (e.g., accurately) estimated and used, for example, to enable a device to recognize high ambient temperature environments and adjust one or more operational parameters (e.g., limits/thresholds), such as a target touch temperature limit, load/power consumption limit, and/or fan profile limit. For example, raising a target touch temperature and/or a fan profile limit in a high temperature environment may (e.g., significantly) improve device performance (e.g., by avoiding performance throttling). Performance adjustments may be more accurate based on more accurate estimates of ambient temperature.

In some examples, a physics-based thermal model may be used for ambient temperature estimation. A physics-based thermal model may be in the form of an ordinary differential equation (ODE). A thermal model may reflect a rate of change of the temperature of a power supply (e.g., a battery) as being proportional to heat generated (e.g., by one or more CPUs) less heat dissipated (e.g., actively, such as by one or more fans, and/or passively, such as by conduction). A model may be tested and validated, for example, using lab thermal testing. For example, measured fan speed, battery temperature, and CPU power in a computing device may be used to estimate ambient temperature (e.g., accurately within a 2 degrees Celsius margin of error).

Concepts described herein may be implemented in existing and new products with multi-purpose (e.g., generic) and/or dedicated measuring devices (e.g., sensors). For example, a battery thermal sensor function may be to monitor a battery temperature. A battery thermal sensor may be one of multiple candidates to provide information to estimate ambient temperature, for example, due to the temperature changing properties of a battery. In contrast to the temperature fluctuations measured by motherboard thermal sensors, battery/battery sensor temperature changes relatively slowly, e.g., due to the thermal mass of the battery. Battery temperature is not influenced quickly based on system loading. However, the impact of ambient temperature on the battery sensor may be relatively weak. Temperature variation of internal thermal sensors may be driven (e.g., mainly) by the heat generated by one or more processors (e.g., CPUs) and heat dissipated by passive and/or active cooling devices (e.g., fans). Passive cooling (e.g., heat passively dissipated to the ambient environment), which depends on the difference between sensor temperature and ambient temperature, may contribute significantly less than active cooling to temperature variation of internal thermal sensors. Data volume for model building may be limited, which may limit the applicability of machine learning models.

In some examples, a model may derive ambient temperature signals, at least in part, from battery temperature sensor data. A model may be in the form of an ordinary differential equation. Parameters may be determined from collected (e.g., empirical) data. A model may be validated through environmental (e.g., thermal) testing. In some examples, a model may utilize the combination of fan speed, battery temperature, and CPU power to estimate ambient temperature accurately (e.g., within an error margin of two Celsius degrees). Other implementations may utilize temperature measurements and information from other areas inside a computing device

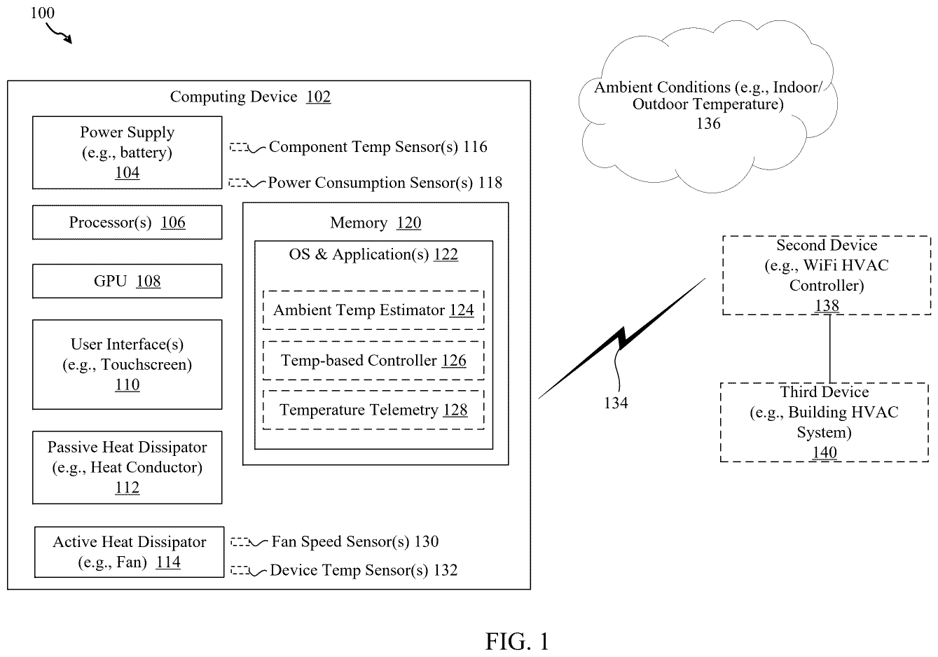

Embodiments may be implemented in a variety of systems/environments. For example, FIG. 1 shows a block diagram of an example computing environment 100 for ambient temperature estimation and device optimization, according to an embodiment. Other examples of ambient temperature estimation and device optimization may be implemented.

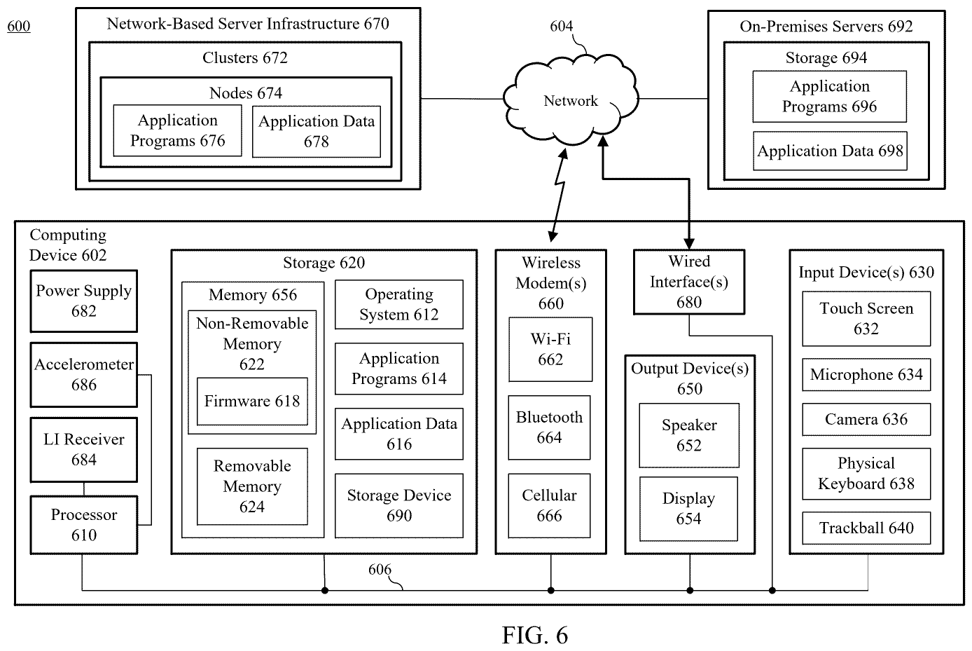

As shown in FIG. 1, computing environment 100 includes computing device 102, which may or may not be communicatively coupled to one or more other devices, such as second device 138, third device 140, etc. A computing environment may be any computing environment (e.g., any combination of hardware, software, and firmware). An example computing device with example features is presented in FIG. 6.

Computing device 102 may be situated in various indoor and/or outdoor environments with one or more ambient conditions 136 that may be estimated by computing device 102. Example computing environment 100 presents one of many possible examples of computing environments. Example computing environment 100 may comprise any number of computing devices and/or servers, such as the example components illustrated in FIG. 1 and other additional or alternative devices not expressly illustrated.

In various examples, computing device 102 may be any type of stationary or mobile computing device, including a mobile computer or mobile computing device (e.g., a Microsoft® Surface® device, a personal digital assistant (PDA), a laptop computer, a notebook computer, a tablet computer such as an Apple iPad™, a netbook, etc.), a mobile phone, a wearable computing device, or other type of mobile device, or a stationary computing device such as a desktop computer or PC (personal computer), or a server.

FIG. 6 shows an example of components in a computing device. Computing device 102 shows some computing components for clarity. Computing device 102 may include, for example, a power supply 104, one or more processors 106, a GPU 108, one or more user interfaces 110, a passive heat dissipator 112, an active heat dissipator 114, one or more component temperature sensors 116, one or more power consumption sensors 118, memory 120, one or more fan speed sensors 130, one or more device temperature sensors 132, etc.

Active heat generators may include, for example, power supply 104, processor(s) 106, and GPU 108. Power supply 104 may include any type of power source, such as a battery in a mobile device. Passive heat generators (e.g., heat traps), although not shown, may include mechanical components. Passive heat generation may be accounted for in passive heat dissipation.

Processor(s) 106 may include any type of processing unit. Processor 106 is an electrical and/or optical circuit implemented in one or more physical hardware electrical circuit device elements and/or integrated circuit devices (e.g., semiconductor material chips or dies) as a central processing unit (CPU), a microcontroller, a microprocessor, and/or other physical hardware processor circuit. Processor 106 may execute program code stored in a computer readable medium, such as program code of operating systems and applications 122, such as ambient temperature (temp) estimator 124, temperature-based (temp-based) controller 126, and/or temperature telemetry 128, etc.

GPU 108 may comprise a graphics processing unit configured to process graphics and render video. GPU 108 may be separate from or integrated with processor(s) 106 (e.g., on a board/card).

Passive heat dissipator 112 may include one or more mechanical components that conduct/transfer and dissipate heat, such as a chassis of computing device 102, one or more heat sinks coupled to heat generating devices, such as power supply 104, processor(s) 106, GPU 108, etc. Heat may be dissipated, for example, to air and/or a coolant (e.g., a liquid).

Active heat dissipator 114 may include one or more powered cooling components, such as one or more fans. Fans may be controlled to operate at one or more discrete/fixed speeds or continuously variable speeds. Speed may be indicated by revolutions per minute (RPM). Fan speed may be associated with noise, which may be measured in decibels (dB).

Component temperature sensor(s) 116 may include one or more temperature sensors, which may be placed on or near one or more components in computing device 102. For example, there may be a CPU temperature sensor, a GPU temperature sensor, a power supply temperature sensor, etc. Component temperature sensor(s) 116 may include one or more types of sensors, such as thermocouples, thermistors, semiconductors, etc.

Power consumption sensor(s) 118 may include one or more component and/or system load or power sensors (e.g., CPU load sensor, GPU load sensor, system load sensor). Power consumption sensor(s) 118 may directly or indirectly detect power consumption. Power consumption sensor(s) 118 may be associated with hardware, firmware and/or software. For example, software may perform calculations on detected voltages, clock frequencies, and/or other indications of loading to calculate/determine (e.g., estimate) power consumption.

Memory 120 may include one or more types of memory, such as read only memory (ROM) 608 and random-access memory (RAM) 610. Memory 120 may store, for loading and execution, OS and application(s) 122, such as ambient temperature (temp) estimator 124, temp-based controller 126, and/or temperature telemetry 128.

Fan speed sensor(s) 130 may detect a control signal or operating speed of a fan (e.g., an active heat dissipator 114). Fan speed sensor(s) 130 may be associated with hardware, firmware and/or software.

Device temperature sensor(s) 132 may include one or more temperature sensors, which may be placed in one or more locations in computing device 102, such as on a chassis or case that a user may touch, near power supply 104, near processor(s) 106, etc. Device temperature sensor(s) 132 may include one or more types of sensors, such as thermocouples, thermistors, semiconductors, etc.

User interface(s) 110 may include, for example, one or more user interfaces, such as a pointing device (e.g., mouse, pen), a typing device (e.g., keyboard), speakers, microphone, display (e.g., touchscreen), graphical user interface (GUI) generated by executed instructions and displayed by a display, etc. For example, an OS and/or application 122 executed by processor(s) 106 may generate a displayed GUI for an administrator (admin) and/or user to interact with to customize power management for computing device 102. A user may indicate, for example, that computing device 102 should maintain performance (e.g., best performance rather than battery life) despite one or more variations (e.g., changes in remaining battery power and/or ambient temperature).

Computing device 102 may include (e.g., execute) one or more operating systems and applications 122, virtual machines (VMs), etc., that may be executed, hosted, and/or stored therein or via one or more other computing devices via network(s) (not shown). Computing device 102 may execute one or more processes in one or more computing environments. A process is an instance of any type of executable (e.g., binary, program, application) that is being executed by computing device 102. A process may include an automated ambient temperature (temp) estimator 124, temp-based controller 126, and/or temperature telemetry 128.

Computing device 102 may be configured to estimate one or more ambient conditions (e.g., indoor/outdoor temperature) 136, for example, using ambient temp estimator 124. Computing device 102 may be configured to provide estimated ambient temperature to temp-based controller 126 and/or temperature telemetry 128.

Computing device 102 may estimate ambient temperature based on information (e.g., data) generated or otherwise collected by computing device 102, such as one or more sensor measurements. As shown by the example in FIG. 1, sensor measurements may include measurements generated by component temp sensor(s) 116, power sensor(s) 118, fan speed sensor(s) 130, device temp sensor(s) 132, etc. Sensor measurements may be collected, for example, periodically (e.g., at a one second interval) and/or based on events.

In some examples, ambient temp estimator 124 may estimate ambient temperature in ambient conditions 136 in accordance with Eq. (1), with parameters described in Table 1.

$$\frac{dB}{dt} = α * C - β * F - γ * ( B - T - Δ T ) \qquad ( 1 )$$

TABLE 1
Example of parameters to estimated ambient temperature

| Parameters | Description |
|---|---|
| B | Power supply (e.g., battery) temperature |
| C | Workload, such as processor (e.g., CPU) power |
| F | Active cooling (e.g., fan speed) |
| T | Ambient temperature |
| ΔT | difference between ambient temperature and local air |
| | temperature around power supply (e.g., battery) |
| α | Workload (e.g., processor) power weight (coefficient) |
| β | Active cooling (e.g., fan speed) weight (coefficient) |
| γ | Passive cooling weight (coefficient) |

Eq. (1) models power supply temperature (e.g., battery sensor temperature (B)) in the form of an ordinary differential equation (ODE). The first term on the right side of Eq. (1) denotes active heat generation, as may be indicated by heat generated from a processor (e.g., CPU (C)). The other two terms, respectively, describe active cooling (e.g., from fans (F)) and passive cooling, which dissipate heat to the ambient environment surrounding computing device 102. The dependence of temperature difference in passive cooling may be governed by Newton's law of cooling. In various implementations, measurements of passive heat generation, active heat generation, passive cooling, active cooling, and their relationship with ambient temperature, as may be indicated in a device-to-ambient temperature model, may be device specific (e.g., component specific) and/or model specific. A device-to-ambient temperature model may be a physics-inspired machine learning (ML) model.

Eq. (1) may be solved for estimated ambient temperature T or Tₑₛₜ, as indicated in Eq. (2).

$${T}_{est} = B - Δ T + \frac{1}{γ} * \frac{dB}{dt} - \frac{α}{γ} * C + \frac{β}{γ} * F \qquad ( 2 )$$

Ambient temperature estimations may be useful for computing device 102 and/or other devices. For example, temp-based controller 126 may use ambient temperature estimations by ambient temp estimator 124 to perform one or more actions, such as control one or more components, dynamically change operating thresholds, etc. Temp-based controller 126 may control components and/or operating thresholds based on ergonomic and/or safety rules, such as long touch temperature limitations and/or acoustic limitations. Temp-based controller 126 may, for example, dynamically (e.g., directly or indirectly) control processor(s) 106, GPU 108, active heat dissipator(s) 114, etc. and/or component operating parameters based on estimated ambient temperature. Temp-based controller 126 may, for example, raise operating thresholds for touch temperature and/or acoustical noise in high ambient temperature environments to maintain performance or provide a performance improvement, thereby avoiding unnecessary throttling of performance that may occur by limiting processor power consumption and/or fan speed when ambient temperature is unknown.

Temperature telemetry 128 may access or receive ambient temperature estimations by ambient temperature estimator and provide them to one or more external devices, such as second device 138. Temperature telemetry 128 may utilize wired and/or wireless transmission capabilities of computing device 102 (not shown) that interface with communication network(s) 134 to provide ambient temperature estimations.

In one of many possible examples, second device 138 may comprise a WiFi HVAC controller, such as an array of WiFi thermostats throughout a building capable of communicating with external devices to receive ambient temperature estimates. Second device 138 may use ambient temperature estimates, for example, to generate a temperature map in a building and control a third device 140 (e.g., building HVAC system) to target heating, cooling, and/or ventilation to more accurately reflect thermostat set temperatures.

Communication network(s) 134 may include one or more public access and/or restricted (e.g., private) access networks, which may be wired and/or wireless. Communication network(s) 134 may include, for example, one or more of any of a local area network (LAN), a wide area network (WAN), a personal area network (PAN), a combination of communication networks, such as the Internet, and/or a virtual network. In example implementations, computing device 102 and one or more other devices, such as second device 138, may be communicatively coupled via communication network(s) 134. In an implementation, computing device 102 and one or more other devices, such as second device 138, may communicate via one or more application programming interfaces (APIs), and/or according to other interfaces and/or techniques. Computing device 102 and one or more other devices, such as second device 138, may include one or more network interfaces that enable communications between devices. Examples of such a network interface, wired or wireless, may include an IEEE 802.11 wireless LAN (WLAN) wireless interface, a Worldwide Interoperability for Microwave Access (Wi-MAX) interface, an Ethernet interface, a Universal Serial Bus (USB) interface, a cellular network interface, a Bluetooth™ interface, a near field communication (NFC) interface, etc. Further examples of network interfaces are described elsewhere herein.

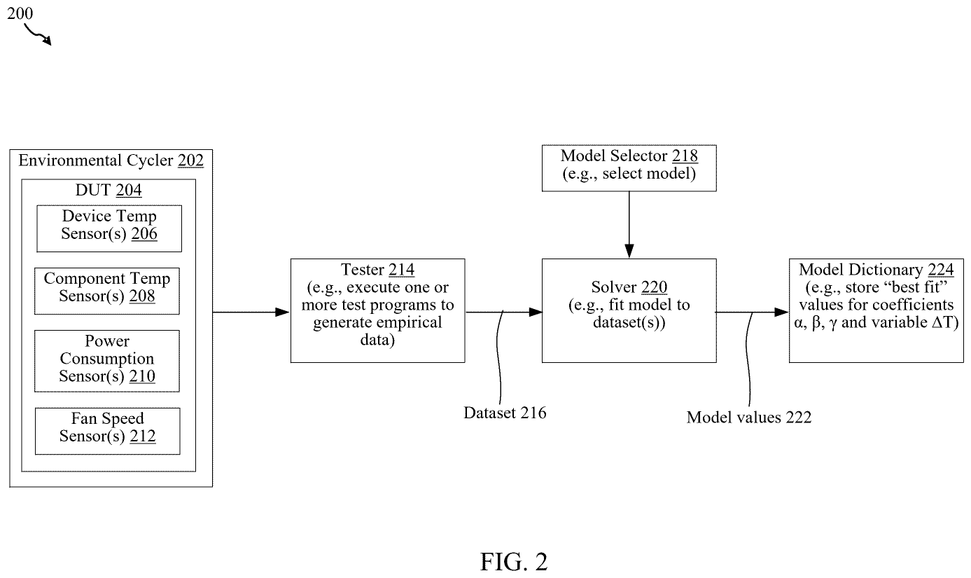

FIGS. 2-4 provide examples for the selection of a model, the generation of values in the model (e.g., training of the model), which may be device-specific and/or model-specific, the use of the model (e.g., by a computing device) to estimate ambient temperature, and the use of the ambient temperature to directly or indirectly control operation of one or more devices (e.g., the computing device or another device). For example, a thermal model may be selected for a device to estimate external (ambient) temperature based on internal device data. The thermal model may be, for example, an ordinary differential equation (ODE). Empirical data may be obtained to develop the selected model (e.g., train the model) based on data/measurements obtained while the device is operated with varying performance cycles in a temperature cycling chamber. A parameter fit may be performed, where values for model coefficients (e.g., weights) and/or variables may be determined by fitting the model to the empirical training data. The thermal model (e.g., the ODE equation) may be numerically solved during the parameter fit. The model may be evaluated (e.g., validated) by testing the model's performance using the determined parameter values and empirical data (e.g., measured data in the dataset) to predict/estimate ambient temperature indicated in the test dataset. Estimated/predicted ambient temperature estimated/predicted by the model may be compared to actual measurements of ambient temperature to validate (e.g., or reject) the model. The model (e.g., a validated model) may be selected and used by a device to estimate/predict ambient temperate based on real-time (e.g., live) measurements generated (e.g., or otherwise received) by the device. The estimated/predicted ambient temperature may be used by the device and/or by one or more other devices. For example, the device may optimize device performance by dynamically adjusting thermal and acoustic limits, which may maintain or improve device performance in high ambient temperature environments.

FIG. 2 shows a block diagram of an example 200 of developing a model for ambient temperature estimation and device optimization, according to an embodiment. A device-to-ambient temperature model may be device and/or model specific. Example 200 shown in FIG. 2 may be used to test multiple devices and multiple models. As shown in FIG. 2, example 200 includes an environmental cycler 202, a device under test (DUT) 204, a tester 214, a model selector 218, a solver 220, and a model dictionary 224.

Environmental cycler 202 may comprise, for example, an environmental testing chamber, such as a thermal cycling chamber. DUT 204 may be placed inside environmental cycler 202 to simulate a wide variety of ambient conditions while DUT 204 undergoes a wide variety of operation, which may generate measurement data for tester 214.

Device under test (DUT) 204 may be any device for which a device-to-ambient model may be constructed. DUT 204 may be, for example, computing device 102 shown in FIG. 1. DUT 204 may include one or more sensors, such as device temperature (temp) sensor(s) 206, component temperature (temp) sensor(s) 208, power consumption sensor(s) 210, fan speed sensor(s) 212, etc. DUT 204 may be communicatively coupled (e.g., wired or wirelessly) to tester 214 during operation of environmental cycler 202 and cycling of operation of DUT 204.

Tester 214 may comprise one or more computing devices configured to control operation of environmental cycler 202, control operation of DUT 204, collect and/or process data, such as measurements within environmental cycler 202 and measurements within DUT 204 during testing. Tester 214 may execute one or more test programs, which may be device-specific and/or model-specific. Tester 214 may generate empirical data (e.g., dataset 216) for evaluation by solver 220. Tester 214 may operate DUT 204 with a variety of workloads while under a variety of constant and varying temperatures in a variety of cycles. In some data collection tests, ambient temperature may vary between stable and unstable, a DUT battery may vary between charging and discharging, performance customization (e.g., Microsoft Windows® power slider) may vary between high performance and battery conservation, processing may vary between stable and intermittent loads at varying levels, test durations may vary, etc.

Dataset 216 may include sensor measurements (e.g., values for measurable variables) generated by environmental cycler 202 (e.g., chamber ambient temperature), DUT 204 (e.g., device temp sensor(s) 206, component temp sensor(s) 208, power consumption sensor(s) 210, fan speed sensor(s) 212), etc. for discrete and/or continuous tests executed by tester 214.

Model selector 218 may select from among one or more models that solver 220 may attempt to fit to dataset 216. A model may be, for example, an algorithm with one or more (e.g., measurable) variables, one or more coefficients (e.g., weights), etc. For example, model selector 218 may select the ODE model shown in Eq. (1), which may be solved for ambient temperature as shown in Eq. (2). In some examples, model selector 218 may select a machine learning (ML) model.

Solver 220 may attempt to fit the model selected by model selector 218 to dataset 216. Solver 220 may determine the (e.g., best) fixed and/or variable values for weights (e.g., coefficients) and variables in the selected model to provide a (e.g., best) fit for the dataset 216, e.g., in terms of predicting actual environment values (e.g., temperature) in environmental cycler 202. In some examples (e.g., during the parameter fit), none or more non-linear minimization methods may be adopted, e.g., to solve the ordinary differential equation (ODE).

Solver 220 may limit data smoothing, for example, given that measured/collected data may be generated at relatively fast (e.g., in terms of seconds) compared to relatively slow variation of ambient temperature (e.g., degree variations in the tens of minutes). Accordingly, data pre-processing procedures on the input data and post-processing on output ambient may be implemented by solver 220.

Data pre-processing may include, for example, averaging measured/collected data (e.g., obtained at one second intervals) over a (e.g., fixed) time window (e.g., 30 seconds). A time-window may be selected, for example, based on the performance (e.g., accuracy) of solver 220.

Data post-processing may include, for example, estimating ambient temperature by calculating a rolling window mean over a window size (e.g., 180 seconds). For example, post-processed data may be the mean of the data from solver 220 in the prior 180 second time window. A time window (e.g., 180 seconds) may be selected based on the performance (e.g., accuracy) of solver 220. As another example, data post-processing may include averaging the data from solver 220 over a (e.g., fixed) time window. The convolution of the data from solver 220 and a fixed time window may be calculated.

Various implementations may utilize various models, such as a physics-based ODE model and/or ML-based models, such as Long Short Term Memory (LSTM) and a spatial-temporal transformer. An ODE model may perform better than an ML model, for example, when there are fewer parameters to learn and/or a limited volume of data. A strategy to solve a data shortage issue may be “inductive bias” or domain knowledge, and/or data augmentation (e.g., using a simulator with high fidelity).

Solver 220 may evaluate and validate the solved model (e.g., with selected values for coefficients and/or variables), for example, using empirical data (e.g., ground truth) information in dataset 216. Solver 220 may generate a set of model values 222 for weights (e.g., coefficients) and/or variables to use in the selected model, such as values for coefficients alpha (α), beta (β), and gamma (γ), and variable delta temp (ΔT), as shown in Eq. (2).

Model dictionary 224 may store (e.g., in accessible file(s)) model values 222 associated with the selected model and DUT 204. Model dictionary 224 may store several sets of values, which may be device-specific and/or model-specific. Model dictionary 224 may be accessed, for example, by ambient temp estimator 124 to apply stored model values 222 and (e.g., real time or live) sensor measurement values (e.g., after preprocessing) by component temp sensor(s) 116, power consumption sensor(s) 118, fan speed sensor(s) 130, device temp sensor(s) 132, etc. to Eq. (2) to generate ambient temperature estimations of ambient conditions 136.

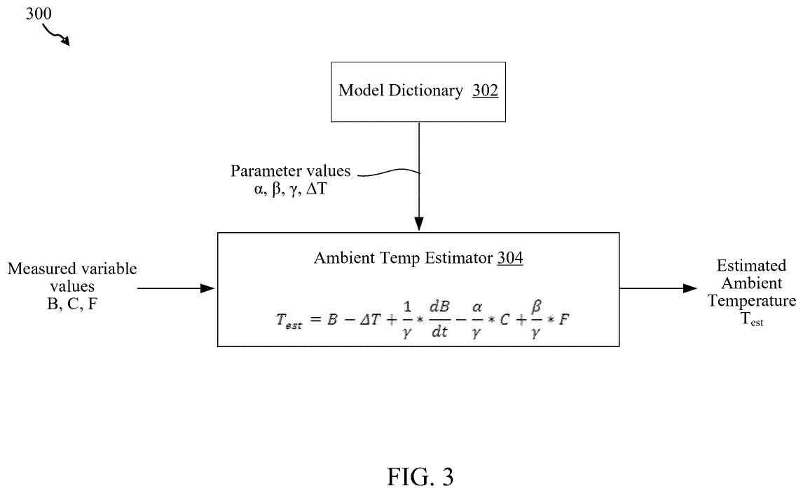

FIG. 3 shows a block diagram of an example 300 of using a model for ambient temperature estimation, according to an embodiment. Example 300 may be implemented by a device that estimates ambient temperature. As shown in FIG. 3, example 300 includes a model dictionary 302 and an ambient temperature (temp) estimator 304.

Model dictionary 302 may be a resource that indicates (e.g., stores/accesses one or more files) parameter values for ambient temp estimator 304. Parameter values (e.g., α, β, γ and ΔT) may be stored in memory accessible by a computing device that estimates ambient temperature. Parameter values (e.g., α, β, γ and ΔT) may be device-specific and/or model-specific. Parameter values may be determined, for example, in the manner shown in FIG. 2. In various examples, model dictionary may be a program that maintains a map of devices and/or models to parameter sets. In some examples, model dictionary 302 may be a look up table (LUT) with a map of devices and/or models to parameter sets.

Ambient temp estimator 304 may (e.g., as shown by example in FIG. 3) estimate ambient temperature in ambient conditions in accordance with Eq. (1), e.g., with parameters described in Table 1. Ambient temp estimator 304 may access model dictionary 302, for example, by providing a device type and/or model type. Model dictionary 302 may provide parameter values to ambient temp estimator 304, for example, based on the device type and/or model type provided by ambient temp estimator 304. In some examples, ambient temp estimator 304 may select a different model (e.g., and parameter set) for different conditions (e.g., device operating conditions, device settings, such as performance settings).

Ambient temp estimator 304 may receive (e.g., in response to a periodic and/or event-based request) measured variable values (e.g., sensor input(s)) B, C, and F (e.g., generated by sensors in the computing device). Ambient temp estimator 304 may (pre) process measured variable values, for example, to normalize the values in accordance with values expected by ambient temp estimator 304.

Ambient temp estimator 304 may use current and previous measured value of power supply temperature (e.g., battery temperature B) to determine a value of dB/dt.

For example, ambient temp estimator 304 may include a function (e.g., getAmbientTemperature) that takes as input the current battery temperature B (e.g., in units dK), the previous battery temperature (e.g., in dK), the fan speed (e.g., in RPM), the CPU power C (e.g., in mW), and a device type identifier (e.g., device_id_enum) indicating the device-specific and/or model-specific parameters to request from model dictionary 302 (e.g., ambientParams dictionary). Parameters received from model dictionary 302 may be placed into variables in the model (e.g., ODE).

Ambient temp estimator 304 may determine (e.g., calculate) estimated ambient temperature Tₑₛₜ by applying measured variable values (e.g., B, C, F) and parameter values (e.g., α, β, γ and ΔT) to the model (e.g., Eq. (2)).

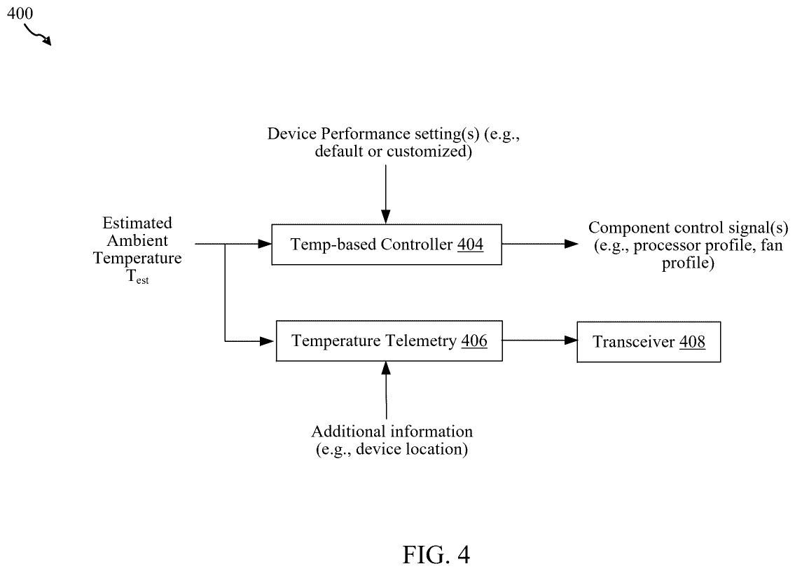

FIG. 4 shows a block diagram of an example 400 of using estimated ambient temperature estimation, according to an embodiment. Example 400 shows several examples of using estimated ambient temperature, such as to maintain/improve (e.g., optimize) device performance and/or to provide telemetry data to another device. Example 400 may be implemented by a device that estimates ambient temperature. As shown in FIG. 4, example 400 includes a temperature-based (temp-based) controller 404, temperature telemetry 406, and a transceiver 408.

Temp-based controller 404 may receive as inputs, for example, estimated ambient temperature Tₑₛₜ and one or more device performance settings. Device performance settings may include, for example, configured (e.g., default or customized) device operation performance rules. For example, a user may interact with Microsoft Windows® Performance Power Slider to indicate preferences relating to device performance, battery life, etc. A performance setting may impact device performance at various ambient temperatures. In an example, a device performance setting indicating maximum performance may allow fan speed, noise, and CPU power consumption to rise at high ambient temperatures.

Temp-based controller 404 may generate one or more outputs (e.g., component control signal(s)), which may be used to perform one or more actions based on received inputs. For example, temp-based controller 404 may (e.g., based on received estimated ambient temperature and/or other inputs, such as performance parameter(s)) dynamically control one or more components, dynamically change operating thresholds, etc. Temp-based controller 404 may control one or more device components and/or operating thresholds based on ergonomic and/or safety rules, such as long touch temperature limitations and/or acoustic limitations. Temp-based controller 404 may, for example, dynamically (e.g., directly or indirectly) control processor(s), GPU, active heat dissipator(s), etc. and/or component operating parameters (e.g., operating profiles/thresholds) based on estimated ambient temperature Tₑₛₜ and device performance setting(s). Temp-based controller 404 may, for example, raise operating thresholds for touch temperature (e.g., target temp profile) and/or acoustical noise (e.g., target fan profile) in high ambient temperature environments to maintain performance or provide a performance improvement, thereby avoiding unnecessary throttling of performance that may occur by limiting processor power consumption and/or fan speed when ambient temperature is unknown.

Temperature telemetry 406 may receive as inputs, for example, estimated ambient temperature Tₑₛₜ and additional information. Temperature telemetry 406 may access or receive ambient temperature estimations by ambient temperature estimator and provide them to one or more external devices. Temperature telemetry 406 may provide telemetry data, such as estimated ambient temperature, device location (e.g., WiFi information, GPS coordinates), etc., to transceiver 408 for transmission to one or more external devices.

Transceiver 408 may utilize any type of communication, whether wired and/or wireless. Transceiver 408 may include one or more communication interfaces (e.g., transmitter, receiver) that enable communications with external devices. Examples of such a network interface, wired or wireless, may include an IEEE 802.11 wireless LAN (WLAN) wireless interface, a Worldwide Interoperability for Microwave Access (Wi-MAX) interface, an Ethernet interface, a Universal Serial Bus (USB) interface, a cellular network interface, a Bluetooth™ interface, a near field communication (NFC) interface, etc. Further examples of communication interfaces are described elsewhere herein.

In one of many possible examples, transceiver 408 may transmit telemetry information to an HVAC controller soliciting information from mobile devices to receive ambient temperature estimates. Second device 138 may use ambient temperature estimates, for example, to generate a temperature map and control a building HVAC system to provide heating, cooling, and/or ventilation. By leveraging the ambient temperature estimates received from the mobile devices, second device 138 can obtain a highly accurate temperature map of the building and then control various aspects of the HVAC system in view of such temperature map to achieve a desired temperature in various areas of the building.

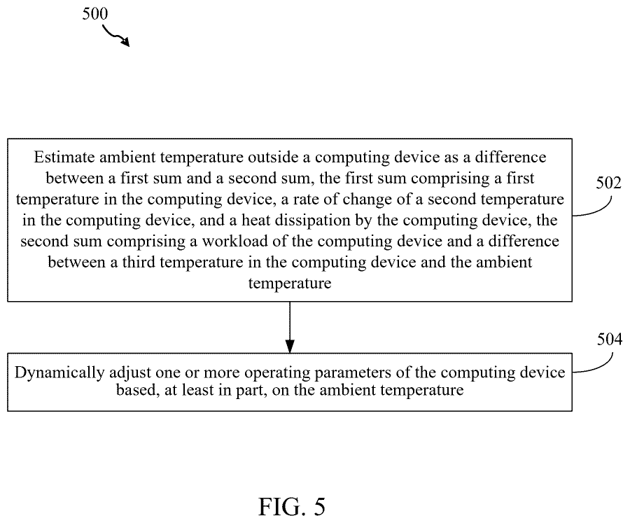

FIG. 5 shows a flowchart of an example method 500 for ambient temperature estimation and device optimization, according to an example embodiment. Embodiments disclosed herein and other embodiments may operate in accordance with example method 500. Method 500 comprises steps 502-504. However, other embodiments may operate according to other methods. Other structural and operational embodiments will be apparent to persons skilled in the relevant art(s) based on the foregoing discussion of embodiments. No steps are required unless expressly indicated or inherently required. No order of steps is required unless expressly indicated or inherently required. There is no requirement that a method embodiment implement all of the steps illustrated in FIG. 5. In various implementations, steps may be added, removed, implemented in the alternative, e.g., in any combination or order. FIG. 5 is simply one of many possible embodiments. Embodiments may implement fewer, more or different steps.

As shown in FIG. 5, in step 502, the ambient temperature outside a computing device may be estimated as a difference between a first sum and a second sum. The first sum may comprise a first temperature in the computing device, a rate of change of a second temperature in the computing device, and a heat dissipation by the computing device. The second sum may comprise a workload of the computing device and a difference between a third temperature in the computing device and the ambient temperature. For example, as shown in FIGS. 1 and 3, ambient temp estimator 124/304 may estimate ambient temperature 136 based on the temperature model shown in Eq. (2), comprising a difference between two sums, where the first sum may comprise a (e.g., weighted) first temperature in the computing device (e.g., battery temp B), a (e.g., weighted) rate of change of a second temperature in the computing device (e.g., dB/dt), and a (e.g., weighted) heat dissipation by the computing device (e.g., fan speed F). The second sum may comprise a (e.g., weighted) workload of the computing device (e.g., CPU power consumption C) and a (e.g., weighted) difference (e.g., ΔT) between a third temperature in the computing device (e.g., internal air temp near battery, such as in a space between the battery and a chassis of the computing device) and the ambient temperature (e.g., T).

As shown in FIG. 5, in step 504, one or more operating parameters of the computing device may be dynamically adjusted based, at least in part, on the ambient temperature. For example, as shown in FIGS. 1 and 4, temp-based controller 126/404 may generate one or more component control signals to dynamically (e.g., directly or indirectly) control processor(s) 106, GPU 108, active heat dissipator 114, etc. and/or component operating parameters based on estimated ambient temperature.

### III. Example Computing Device Embodiments

As noted herein, the embodiments described, along with any circuits, components and/or subcomponents thereof, as well as the flowcharts/flow diagrams described herein, including portions thereof, and/or other embodiments, may be implemented in hardware, or hardware with any combination of software and/or firmware, including being implemented as computer program code configured to be executed in one or more processors and stored in a computer readable storage medium, or being implemented as hardware logic/electrical circuitry, such as being implemented together in a system-on-chip (SoC), a field programmable gate array (FPGA), and/or an application specific integrated circuit (ASIC). A SOC may include an integrated circuit chip that includes one or more of a processor (e.g., a microcontroller, microprocessor, digital signal processor (DSP), etc.), memory, one or more communication interfaces, and/or further circuits and/or embedded firmware to perform its functions.

Embodiments disclosed herein may be implemented in one or more computing devices that may be mobile (a mobile device) and/or stationary (a stationary device) and may include any combination of the features of such mobile and stationary computing devices. Examples of computing devices in which embodiments may be implemented are described as follows with respect to FIG. 6. FIG. 6 shows a block diagram of an exemplary computing environment 600 that includes a computing device 602. Computing device 602 is an example of computing device 102 of FIG. 1, which may include one or more of the components of computing device 602. In some embodiments, computing device 602 is communicatively coupled with devices (not shown in FIG. 6) external to computing environment 600 via network 604. Network 604 comprises one or more networks such as local area networks (LANs), wide area networks (WANs), enterprise networks, the Internet, etc., and may include one or more wired and/or wireless portions. Network 604 may additionally or alternatively include a cellular network for cellular communications. Computing device 602 is described in detail as follows

Computing device 602 can be any of a variety of types of computing devices. For example, computing device 602 may be a mobile computing device such as a handheld computer (e.g., a personal digital assistant (PDA)), a laptop computer, a tablet computer (such as an Apple iPad™), a hybrid device, a notebook computer (e.g., a Google Chromebook™ by Google LLC), a netbook, a mobile phone (e.g., a cell phone, a smart phone such as an Apple® iPhone® by Apple Inc., a phone implementing the Google® Android™ operating system, etc.), a wearable computing device (e.g., a head-mounted augmented reality and/or virtual reality device including smart glasses such as Google® Glass™, Oculus Rift® of Facebook Technologies, LLC, etc.), or other type of mobile computing device. Computing device 602 may alternatively be a stationary computing device such as a desktop computer, a personal computer (PC), a stationary server device, a minicomputer, a mainframe, a supercomputer, etc.

As shown in FIG. 6, computing device 602 includes a variety of hardware and software components, including a processor 610, a storage 620, one or more input devices 630, one or more output devices 650, one or more wireless modems 660, one or more wired interfaces 680, a power supply 682, a location information (LI) receiver 684, and an accelerometer 686. Storage 620 includes memory 656, which includes non-removable memory 622 and removable memory 624, and a storage device 690. Storage 620 also stores an operating system 612, application programs 614, and application data 616. Wireless modem(s) 660 include a Wi-Fi modem 662, a Bluetooth modem 664, and a cellular modem 666. Output device(s) 650 includes a speaker 652 and a display 654. Input device(s) 630 includes a touch screen 632, a microphone 634, a camera 636, a physical keyboard 638, and a trackball 640. Not all components of computing device 602 shown in FIG. 6 are present in all embodiments, additional components not shown may be present, and any combination of the components may be present in a particular embodiment. These components of computing device 602 are described as follows.

A single processor 610 (e.g., central processing unit (CPU), microcontroller, a microprocessor, signal processor, ASIC (application specific integrated circuit), and/or other physical hardware processor circuit) or multiple processors 610 may be present in computing device 602 for performing such tasks as program execution, signal coding, data processing, input/output processing, power control, and/or other functions. Processor 610 may be a single-core or multi-core processor, and each processor core may be single-threaded or multithreaded (to provide multiple threads of execution concurrently). Processor 610 is configured to execute program code stored in a computer readable medium, such as program code of operating system 612 and application programs 614 stored in storage 620. Operating system 612 controls the allocation and usage of the components of computing device 602 and provides support for one or more application programs 614 (also referred to as “applications” or “apps”). Application programs 614 may include common computing applications (e.g., e-mail applications, calendars, contact managers, web browsers, messaging applications), further computing applications (e.g., word processing applications, mapping applications, media player applications, productivity suite applications), one or more machine learning (ML) models, as well as applications related to the embodiments disclosed elsewhere herein.

Any component in computing device 602 can communicate with any other component according to function, although not all connections are shown for ease of illustration. For instance, as shown in FIG. 6, bus 606 is a multiple signal line communication medium (e.g., conductive traces in silicon, metal traces along a motherboard, wires, etc.) that may be present to communicatively couple processor 610 to various other components of computing device 602, although in other embodiments, an alternative bus, further buses, and/or one or more individual signal lines may be present to communicatively couple components. Bus 606 represents one or more of any of several types of bus structures, including a memory bus or memory controller, a peripheral bus, an accelerated graphics port, and a processor or local bus using any of a variety of bus architectures.

Storage 620 is physical storage that includes one or both of memory 656 and storage device 690, which store operating system 612, application programs 614, and application data 616 according to any distribution. Non-removable memory 622 includes one or more of RAM (random access memory), ROM (read only memory), flash memory, a solid-state drive (SSD), a hard disk drive (e.g., a disk drive for reading from and writing to a hard disk), and/or other physical memory device type. Non-removable memory 622 may include main memory and may be separate from or fabricated in a same integrated circuit as processor 610. As shown in FIG. 6, non-removable memory 622 stores firmware 618, which may be present to provide low-level control of hardware. Examples of firmware 618 include BIOS (Basic Input/Output System, such as on personal computers) and boot firmware (e.g., on smart phones). Removable memory 624 may be inserted into a receptacle of or otherwise coupled to computing device 602 and can be removed by a user from computing device 602. Removable memory 624 can include any suitable removable memory device type, including an SD (Secure Digital) card, a Subscriber Identity Module (SIM) card, which is well known in GSM (Global System for Mobile Communications) communication systems, and/or other removable physical memory device type. One or more of storage device 690 may be present that are internal and/or external to a housing of computing device 602 and may or may not be removable. Examples of storage device 690 include a hard disk drive, a SSD, a thumb drive (e.g., a USB (Universal Serial Bus) flash drive), or other physical storage device.

One or more programs may be stored in storage 620. Such programs include operating system 612, one or more application programs 614, and other program modules and program data. Examples of such application programs may include, for example, computer program logic (e.g., computer program code/instructions) for implementing one or more of ambient temp estimator 124, temp-based controller 126, temperature telemetry 128, ambient temp estimator 304, temp-based controller 404, temperature telemetry 406, along with any components and/or subcomponents thereof, as well as the flowcharts/flow diagrams (e.g., method 500) described herein, including portions thereof, and/or further examples described herein.

Storage 620 also stores data used and/or generated by operating system 612 and application programs 614 as application data 616. Examples of application data 616 include web pages, text, images, tables, sound files, video data, and other data, which may also be sent to and/or received from one or more network servers or other devices via one or more wired or wireless networks. Storage 620 can be used to store further data including a subscriber identifier, such as an International Mobile Subscriber Identity (IMSI), and an equipment identifier, such as an International Mobile Equipment Identifier (IMEI). Such identifiers can be transmitted to a network server to identify users and equipment.

A user may enter commands and information into computing device 602 through one or more input devices 630 and may receive information from computing device 602 through one or more output devices 650. Input device(s) 630 may include one or more of touch screen 632, microphone 634, camera 636, physical keyboard 638 and/or trackball 640 and output device(s) 650 may include one or more of speaker 652 and display 654. Each of input device(s) 630 and output device(s) 650 may be integral to computing device 602 (e.g., built into a housing of computing device 602) or external to computing device 602 (e.g., communicatively coupled wired or wirelessly to computing device 602 via wired interface(s) 680 and/or wireless modem(s) 660). Further input devices 630 (not shown) can include a Natural User Interface (NUI), a pointing device (computer mouse), a joystick, a video game controller, a scanner, a touch pad, a stylus pen, a voice recognition system to receive voice input, a gesture recognition system to receive gesture input, or the like. Other possible output devices (not shown) can include piezoelectric or other haptic output devices. Some devices can serve more than one input/output function. For instance, display 654 may display information, as well as operating as touch screen 632 by receiving user commands and/or other information (e.g., by touch, finger gestures, virtual keyboard, etc.) as a user interface. Any number of each type of input device(s) 630 and output device(s) 650 may be present, including multiple microphones 634, multiple cameras 636, multiple speakers 652, and/or multiple displays 654.

One or more wireless modems 660 can be coupled to antenna(s) (not shown) of computing device 602 and can support two-way communications between processor 610 and devices external to computing device 602 through network 604, as would be understood to persons skilled in the relevant art(s). Wireless modem 660 is shown generically and can include a cellular modem 666 for communicating with one or more cellular networks, such as a GSM network for data and voice communications within a single cellular network, between cellular networks, or between the mobile device and a public switched telephone network (PSTN). Wireless modem 660 may also or alternatively include other radio-based modem types, such as a Bluetooth modem 664 (also referred to as a “Bluetooth device”) and/or Wi-Fi 662 modem (also referred to as an “wireless adaptor”). Wi-Fi modem 662 is configured to communicate with an access point or other remote Wi-Fi-capable device according to one or more of the wireless network protocols based on the IEEE (Institute of Electrical and Electronics Engineers) 802.11 family of standards, commonly used for local area networking of devices and Internet access. Bluetooth modem 664 is configured to communicate with another Bluetooth-capable device according to the Bluetooth short-range wireless technology standard(s) such as IEEE 802.15.1 and/or managed by the Bluetooth Special Interest Group (SIG).

Computing device 602 can further include power supply 682, LI receiver 684, accelerometer 686, and/or one or more wired interfaces 680. Example wired interfaces 680 include a USB port, IEEE 1394 (FireWire) port, a RS-232 port, an HDMI (High-Definition Multimedia Interface) port (e.g., for connection to an external display), a DisplayPort port (e.g., for connection to an external display), an audio port, an Ethernet port, and/or an Apple® Lightning® port, the purposes and functions of each of which are well known to persons skilled in the relevant art(s). Wired interface(s) 680 of computing device 602 provide for wired connections between computing device 602 and network 604, or between computing device 602 and one or more devices/peripherals when such devices/peripherals are external to computing device 602 (e.g., a pointing device, display 654, speaker 652, camera 636, physical keyboard 638, etc.). Power supply 682 is configured to supply power to each of the components of computing device 602 and may receive power from a battery internal to computing device 602, and/or from a power cord plugged into a power port of computing device 602 (e.g., a USB port, an A/C power port). LI receiver 684 may be used for location determination of computing device 602 and may include a satellite navigation receiver such as a Global Positioning System (GPS) receiver or may include other type of location determiner configured to determine location of computing device 602 based on received information (e.g., using cell tower triangulation, etc.). Accelerometer 686 may be present to determine an orientation of computing device 602.

Note that the illustrated components of computing device 602 are not required or all-inclusive, and fewer or greater numbers of components may be present as would be recognized by one skilled in the art. For example, computing device 602 may also include one or more of a gyroscope, barometer, proximity sensor, ambient light sensor, digital compass, etc. Processor 610 and memory 656 may be co-located in a same semiconductor device package, such as being included together in an integrated circuit chip, FPGA, or system-on-chip (SOC), optionally along with further components of computing device 602.

In embodiments, computing device 602 is configured to implement any of the above-described features of flowcharts herein. Computer program logic for performing any of the operations, steps, and/or functions described herein may be stored in storage 620 and executed by processor 610.

In some embodiments, server infrastructure 670 may be present in computing environment 600 and may be communicatively coupled with computing device 602 via network 604. Server infrastructure 670, when present, may be a network-accessible server set (e.g., a cloud-based environment or platform). As shown in FIG. 6, server infrastructure 670 includes clusters 672. Each of clusters 672 may comprise a group of one or more compute nodes and/or a group of one or more storage nodes. For example, as shown in FIG. 6, cluster 672 includes nodes 674. Each of nodes 674 are accessible via network 604 (e.g., in a “cloud-based” embodiment) to build, deploy, and manage applications and services. Any of nodes 674 may be a storage node that comprises a plurality of physical storage disks, SSDs, and/or other physical storage devices that are accessible via network 604 and are configured to store data associated with the applications and services managed by nodes 674. For example, as shown in FIG. 6, nodes 674 may store application data 678.

Each of nodes 674 may, as a compute node, comprise one or more server computers, server systems, and/or computing devices. For instance, a node 674 may include one or more of the components of computing device 602 disclosed herein. Each of nodes 674 may be configured to execute one or more software applications (or “applications”) and/or services and/or manage hardware resources (e.g., processors, memory, etc.), which may be utilized by users (e.g., customers) of the network-accessible server set. For example, as shown in FIG. 6, nodes 674 may operate application programs 676. In an implementation, a node of nodes 674 may operate or comprise one or more virtual machines, with each virtual machine emulating a system architecture (e.g., an operating system), in an isolated manner, upon which applications such as application programs 676 may be executed.

In an embodiment, one or more of clusters 672 may be co-located (e.g., housed in one or more nearby buildings with associated components such as backup power supplies, redundant data communications, environmental controls, etc.) to form a datacenter, or may be arranged in other manners. Accordingly, in an embodiment, one or more of clusters 672 may be a datacenter in a distributed collection of datacenters. In embodiments, exemplary computing environment 600 comprises part of a cloud-based platform such as Amazon Web Services® of Amazon Web Services, Inc. or Google Cloud Platform™ of Google LLC, although these are only examples and are not intended to be limiting.

In an embodiment, computing device 602 may access application programs 676 for execution in any manner, such as by a client application and/or a browser at computing device 602. Example browsers include Microsoft Edge® by Microsoft Corp. of Redmond, Washington, Mozilla Firefox®, by Mozilla Corp. of Mountain View, California, Safari®, by Apple Inc. of Cupertino, California, and Google® Chrome by Google LLC of Mountain View, California.

For purposes of network (e.g., cloud) backup and data security, computing device 602 may additionally and/or alternatively synchronize copies of application programs 614 and/or application data 616 to be stored at network-based server infrastructure 670 as application programs 676 and/or application data 678. For instance, operating system 612 and/or application programs 614 may include a file hosting service client, such as Microsoft® OneDrive® by Microsoft Corporation, Amazon Simple Storage Service (Amazon S3)® by Amazon Web Services, Inc., Dropbox® by Dropbox, Inc., Google Drive™ by Google LLC, etc., configured to synchronize applications and/or data stored in storage 620 at network-based server infrastructure 670.

In some embodiments, on-premises servers 692 may be present in computing environment 600 and may be communicatively coupled with computing device 602 via network 604. On-premises servers 692, when present, are hosted within an organization's infrastructure and, in many cases, physically onsite of a facility of that organization. On-premises servers 692 are controlled, administered, and maintained by IT (Information Technology) personnel of the organization or an IT partner to the organization. Application data 698 may be shared by on-premises servers 692 between computing devices of the organization, including computing device 602 (when part of an organization) through a local network of the organization, and/or through further networks accessible to the organization (including the Internet). Furthermore, on-premises servers 692 may serve applications such as application programs 696 to the computing devices of the organization, including computing device 602. Accordingly, on-premises servers 692 may include storage 694 (which includes one or more physical storage devices such as storage disks and/or SSDs) for storage of application programs 696 and application data 698 and may include one or more processors for execution of application programs 696. Still further, computing device 602 may be configured to synchronize copies of application programs 614 and/or application data 616 for backup storage at on-premises servers 692 as application programs 696 and/or application data 698.

Embodiments described herein may be implemented in one or more of computing device 602, network-based server infrastructure 670, and on-premises servers 692. For example, in some embodiments, computing device 602 may be used to implement systems, clients, or devices, or components/subcomponents thereof, disclosed elsewhere herein. In other embodiments, a combination of computing device 602, network-based server infrastructure 670, and/or on-premises servers 692 may be used to implement the systems, clients, or devices, or components/subcomponents thereof, disclosed elsewhere herein.

As used herein, the terms “computer program medium,” “computer-readable medium,” and “computer-readable storage medium,” etc., are used to refer to physical hardware media. Examples of such physical hardware media include any hard disk, optical disk, SSD, other physical hardware media such as RAMs, ROMs, flash memory, digital video disks, zip disks, MEMs (microelectronic machine) memory, nanotechnology-based storage devices, and further types of physical/tangible hardware storage media of storage 620. Such computer-readable media and/or storage media are distinguished from and non-overlapping with communication media and propagating signals (do not include communication media and propagating signals). Communication media embodies computer-readable instructions, data structures, program modules or other data in a modulated data signal such as a carrier wave. The term “modulated data signal” means a signal that has one or more of its characteristics set or changed in such a manner as to encode information in the signal. By way of example, and not limitation, communication media includes wireless media such as acoustic, RF, infrared and other wireless media, as well as wired media. Embodiments are also directed to such communication media that are separate and non-overlapping with embodiments directed to computer-readable storage media.

As noted above, computer programs and modules (including application programs 614) may be stored in storage 620. Such computer programs may also be received via wired interface(s) 680 and/or wireless modem(s) 660 over network 604. Such computer programs, when executed or loaded by an application, enable computing device 602 to implement features of embodiments discussed herein. Accordingly, such computer programs represent controllers of the computing device 602.

Embodiments are also directed to computer program products comprising computer code or instructions stored on any computer-readable medium or computer-readable storage medium. Such computer program products include the physical storage of storage 620 as well as further physical storage types.

### IV. Further Example Embodiments

Methods, systems and computer program products are provided for ambient temperature estimation and device optimization. A (e.g., mobile) computing device may include a temperature estimator configured to estimate (e.g., predict based on a thermal model) an ambient temperature outside the computing device as a difference between a first sum and a second sum. The first sum may comprise, for example, one or more of a first temperature in the computing device (e.g., a temperature of a power supply, such as a battery) and a rate of change of a second temperature in the computing device. The second sum may comprise, for example, one or more of a computing device workload (e.g., system, CPU and/or GPU power consumption); and/or a difference between a third temperature in the computing device (e.g., internal air temperature near a power supply, such as in a space between the power supply and a chassis of the computing device) and the ambient temperature.

In examples, the first sum may (e.g., further) comprise heat dissipation by the computing device (e.g., passive dissipation, such as conduction, and/or active dissipation, such as a fan).

In examples, the heat dissipation may be based, at least in part, on active heat dissipation.

In examples, active heat dissipation may be based on or indicated by fan speed.

In examples, the workload of the computing device may be based, at least in part, on, power consumption by a processor.

In examples, the first temperature in the computing device may be the same as or different from the second temperature in the computing device.

In examples, the first and/or second temperatures in the computing device may comprise a temperature of a first component in the computing device (e.g., for a power supply, such as a battery in a portable device).

In examples, the rate of change of the second temperature in the computing device may comprise a rate of change of the temperature of a component in the computing device (e.g., for a power supply, such as a battery in a portable device).

In examples, at least one of the first temperature in the computing device, the rate of change of a second temperature in the computing device, the workload of the computing device, and/or the difference between a third temperature in the computing device and the ambient temperature may be weighted. Weights may be determined, for example, by empirical test data.

In examples, a computing device may be a fixed location device or a mobile device.

In examples, a computing device may (e.g., further) comprise a controller configured to dynamically adjust one or more operating parameters of the computing device, (e.g., thermal and/or acoustic thresholds or operation of one or more components in the computing device) based, at least in part, on the ambient temperature.

In examples, a computing device may (e.g., further) comprise a transmitter configured to transmit an indication of the ambient temperature (e.g., a control signal) to a second device external to the computing device (e.g., a WiFi thermostat) to control operation of the second device or a third device external to the computing device (e.g., an HVAC system) based, at least in part, on the ambient temperature.

In examples, a computer-implemented method may comprise estimating ambient temperature outside a computing device as a difference between a first sum and a second sum. The first sum may comprise a first temperature in the computing device (e.g., a temperature of a power supply, such as a battery, a temperature of a motherboard, and so on); a rate of change of a second temperature in the computing device; and a heat dissipation by the computing device (e.g., passive dissipation, such as conduction, and/or active dissipation, such as a fan operating at a selected speed). The second sum may comprises a workload of the computing device (e.g., system, CPU and/or GPU power consumption) and a difference between a third temperature in the computing device (e.g., internal air temperature near a power supply, such as in a space between the power supply and a chassis of the computing device) and the ambient temperature.

In examples, the first temperature in the computing device may be the same as the second temperature in the computing device.

In examples, the heat dissipation may be based on active heat dissipation and/or passive heat dissipation.

In examples, the first and second temperatures may be based on a power supply temperature. The third temperature may be based on a temperature in a space between the power supply and a chassis of the computing device. The active heat dissipation may be based, at least in part, on a fan speed. The workload of the computing device may be based, at least in part, on power consumption by a processor.

In examples, a method may (e.g., further) comprise dynamically adjusting one or more operating parameters of the computing device (e.g., dynamically adjust thermal and/or acoustic thresholds or operation of one or more components in the computing device) based, at least in part, on the ambient temperature.

In examples, a computer-readable storage medium may have program instructions recorded thereon that, when executed by a processing circuit, perform a method. The method may comprise estimating ambient temperature outside a computing device as a difference between a first sum and a second sum. The first sum may comprise a first temperature in the computing device (e.g., a temperature of a power supply, such as a battery, a temperature of a motherboard, and so on), a rate of change of a second temperature in the computing device, and a heat dissipation by the computing device (e.g., passive dissipation, such as conduction, and/or active dissipation, such as a fan operating at a selected speed). The second sum may comprises a workload of the computing device (e.g., system, CPU and/or GPU power consumption) and a difference between a third temperature in the computing device (e.g., internal air temperature near a power supply, e.g. in a space between the power supply and a chassis of the computing device) and the ambient temperature. The method may comprise dynamically adjusting one or more operating parameters of the computing device based, at least in part, on the ambient temperature; and/or transmitting the ambient temperature or a control signal to a second device external to the computing device to control operation of the second device or a third device external to the computing device based, at least in part, on the ambient temperature.

In examples, the first temperature in the computing device may be the same as the second temperature in the computing device.

In examples, the first and second temperatures may be based on a power supply temperature. The third temperature may be based on a temperature in a space between the power supply and a chassis of the computing device. The heat dissipation may be based, at least in part, on a fan speed. The workload of the computing device may be based, at least in part, on power consumption by a processor.

In an example of estimating an ambient temperature (e.g., the temperature outside of a device), e.g., for performance/thermal optimization of components in the device, the device may measure factors associated with operation of internal parts of the computing device, such as by measuring rotational speed of cooling fan, power consumed by processing unit (CPU) and battery temperature. The device may estimate the ambient temperature by using the measured factors in a model (e.g., a formula or algorithm). The model may be related to an estimate of heat dissipation by the computing device. The model may correspond to an ordinary differential equation describing the rate of change of the battery temperature as proportional to the heat generated by the CPU subtracted by the amount of heat dissipated from the fans and the amount of heat dissipated by conduction (e.g., dB/dt=a*C−β *F−γ *(B-T-ΔT), where C is CPU power, F is fan speed, B is battery temperature, T is ground-truth ambient temperature, and ΔT is the difference between ambient temperature and the local air temperature around battery). Parameters (e.g., α, β, γ, ΔT) used in the model may be determined by fitting (e.g., parameter fitting) the collected factors (e.g., battery temperature data “B,” CPU power “C,” fan speed “F,” and ground-truth ambient temperature “T”) as training data to the model. The model (e.g., solved for estimated temperature Tₑₛₜ=B−ΔT+((1/γ)*dB/dt)−((α/γ)*C)+((β/γ)*F)) may be used to estimate ambient temperature based on the determined parameters and (e.g., real-time or live) measured factors. The computing device may use the estimated ambient temperature to control operation of one or more components in the device, for example, by adjusting acoustic and/or power thresholds to avoid throttling at high ambient temperatures, e.g., while satisfying ergonomic and/or safety rules.

### V. Conclusion

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an example embodiment, it is submitted that it is within the knowledge of one skilled in the art to effect such feature, structure, or characteristic in connection with other embodiments whether or not explicitly described.

In the discussion, unless otherwise stated, adjectives such as “substantially” and “about” modifying a condition or relationship characteristic of a feature or features of an example embodiment of the disclosure, are understood to mean that the condition or characteristic is defined to within tolerances that are acceptable for operation of the embodiment for an application for which it is intended.

If the performance of an operation is described herein as being “based on” one or more factors, it is to be understood that the performance of the operation may be based solely on such factor(s) or may be based on such factor(s) along with one or more additional factors. Thus, as used herein, the term “based on” should be understood to be equivalent to the term “based at least on.”

While various embodiments of the present invention have been described above, it should be understood that they have been presented by way of example only, and not limitation. It will be understood by those skilled in the relevant art(s) that various changes in form and details may be made therein without departing from the spirit and scope of the invention as defined in the appended claims. Accordingly, the breadth and scope of the present invention should not be limited by any of the above-described exemplary embodiments, but should be defined only in accordance with the following claims and their equivalents.

What is claimed is:

1. A computing device comprising:
a temperature estimator configured to determine an ambient temperature outside the computing device as a difference between a first sum and a second sum;
wherein the first sum comprises:
a first temperature in the computing device; and
a rate of change of a second temperature in the computing device; and
wherein the second sum comprises:
a workload of the computing device; and
a difference between a third temperature in the computing device and the ambient temperature.

2. The computing device of claim 1, wherein the first sum further comprises:
a heat dissipation by the computing device.

3. The computing device of claim 2, wherein the heat dissipation is based, at least in part, on an active heat dissipation.

4. The computing device of claim 3, wherein the active heat dissipation is based, at least in part, on a fan speed.

5. The computing device of claim 1, wherein the workload of the computing device is based, at least in part on, power consumption by a processor.

6. The computing device of claim 1, wherein the first temperature in the computing device is the same as the second temperature in the computing device.

7. The computing device of claim 6, wherein the first and second temperatures in the computing device comprise a temperature of a first component in the computing device.

8. The computing device of claim 1, wherein the rate of change of the second temperature in the computing device comprises a rate of change of the temperature of a first component in the computing device.

9. The computing device of claim 1, wherein at least one of the first temperature in the computing device, the rate of change of the second temperature in the computing device, the workload of the computing device, or the difference between the third temperature in the computing device and the ambient temperature is weighted.

10. The computing device of claim 1, wherein the computing device comprises a mobile device.

11. The computing device of claim 1, further comprising:
a controller configured to dynamically adjust one or more operating parameters of the computing device based, at least in part, on the ambient temperature.

12. The computing device of claim 1, further comprising:
a transmitter configured to transmit an indication of the ambient temperature to a second device device external to the computing device to control operation of the second device or a third device external to the computing device based, at least in part, on the ambient temperature.

13. A computer-implemented method comprising:
estimating ambient temperature outside a computing device as a difference between a first sum and a second sum;
wherein the first sum comprises:
a first temperature in the computing device;
a rate of change of a second temperature in the computing device; and
a heat dissipation by the computing device; and
wherein the second sum comprises:
a workload of the computing device; and
a difference between a third temperature in the computing device and the ambient temperature.

14. The computer-implemented method of claim 13, wherein the first temperature in the computing device is the same as the second temperature in the computing device.

15. The computer-implemented method of claim 13, wherein the heat dissipation is based on active heat dissipation and passive heat dissipation.

16. The computer-implemented method of claim 15, wherein the first and second temperatures are based on a power supply temperature, wherein the third temperature is based on a temperature in a space between the power supply and a chassis of the computing device, wherein the active heat dissipation is based, at least in part, on a fan speed, and wherein the workload of the computing device is based, at least in part, on power consumption by a processor.

17. The computer-implemented method of claim 13, further comprising:
dynamically adjusting one or more operating parameters of the computing device based, at least in part, on the ambient temperature.

18. A computer-readable storage medium having program instructions recorded thereon that, when executed by a processing circuit, perform a method comprising:
estimating ambient temperature outside a computing device as a difference between a first sum and a second sum;
wherein the first sum comprises:
a first temperature in the computing device;
a rate of change of a second temperature in the computing device; and
a heat dissipation by the computing device; and
wherein the second sum comprises:
a workload of the computing device; and
a difference between a third temperature in the computing device and the ambient temperature; and
dynamically adjusting one or more operating parameters of the computing device based, at least in part, on the ambient temperature; or
transmitting the ambient temperature or a control signal to a second device device external to the computing device to control operation of the second device or a third device external to the computing device based, at least in part, on the ambient temperature.

19. The computer-readable storage medium of claim 18, wherein the first temperature in the computing device is the same as the second temperature in the computing device.

20. The computer-readable storage medium of claim 19, wherein the first and second temperatures are based on a power supply temperature, wherein the third temperature is based on a temperature in a space between the power supply and a chassis of the computing device, wherein the heat dissipation is based, at least in part, on a fan speed, and wherein the workload of the computing device is based, at least in part, on power consumption by a processor.
